(19) United States
(12) Patent Application Publication
(10) Pub. No.: US 2026/0001755 A1
(43) Pub. Date: Jan. 1, 2026

(54) FUNCTIONALIZED OXOACID LUBRICANTS IN MEMS DEVICES

(71) Applicant: TEXAS INSTRUMENTS INCORPORATED, Dallas, TX (US)

(72) Inventors: John Faruk ALPTEKIN, Carrollton, TX (US); Uroob HARIS, Sachse, TX (US); Muralidhar HANABE, Allen, TX (US)

(21) Appl. No.: 18/758,421

(22) Filed: Jun. 28, 2024

(51) Int. Cl. B81B 3/00; B81C 1/00; C10M 105/74; C10N 40/14; C10N 50/02; G02B 26/08

(52) U.S. Cl. CPC B81B 3/0005; B81C 1/00968; C10M 105/74; G02B 26/0833; B81B 2201/042; C10M 2223/0405; C10M 2223/0603; C10N 2040/14; C10N 2050/02

(57) ABSTRACT

In examples, a microelectromechanical systems (MEMS) device comprises a moveable element configured to contact a portion of a surface, and a film formed of a self-assembled lubricant, the lubricant comprising a compound having (i) an oxoacid moiety and (ii) a hydrophobic moiety with an A value of equal to or greater than about 3 kilocalories/mole on the portion of the surface.

### BACKGROUND

Microelectromechanical systems (MEMS) devices are micron-scale electromechanical structures made using specialized semiconductor manufacturing techniques. MEMS devices integrate mechanical and electrical components on a single chip, enabling sensors, actuators, and other devices with high precision.

### SUMMARY

In examples, a microelectromechanical systems (MEMS) device comprises a moveable element configured to contact a portion of a surface, and a film formed of a self-assembled lubricant, the lubricant comprising a compound having (i) an oxoacid moiety and (ii) a hydrophobic moiety with an A value of equal to or greater than about 3 kilocalories/mole on the portion of the surface.

In examples, a method includes obtaining a microelectromechanical systems (MEMS) device and contacting one or more surfaces of the MEMS device with a lubricant under conditions suitable for formation of a film on at least a portion of the one or more surfaces of the device, where contacting is carried out by deposition, chemical vapor deposition, dip coating, aerosol coating, spray coating, or any combination thereof. The lubricant includes a compound having (i) an oxoacid moiety and (ii) a hydrophobic moiety with an A value of equal to or greater than about 3 kilocalories/mole on the portion of the one or more surfaces of the device. The method also includes bonding the lubricant to the one or more surfaces of the device by heating the lubricant to a temperature of from about 25° C. to about 200° C.

### BRIEF DESCRIPTION OF THE DRAWINGS

FIGS. 1A and 1B are schematic diagrams representing functionalized oxoacids interacting with surfaces for lubricating MEMS devices to mitigate stiction, in accordance with various examples.

FIG. 2 is a flow diagram of a method for manufacturing a MEMS device lubricated with anti-stiction functionalized oxoacid liquids, in accordance with various examples.

FIG. 3 is a block diagram of a MEMS device lubricated with an anti-stiction functionalized oxoacid, in accordance with various examples.

FIGS. 4A-4C are schematic diagrams of a digital micromirror device (DMD) lubricated with an anti-stiction functionalized oxoacid, in accordance with various examples.

FIG. 5 is a schematic diagram of an accelerometer lubricated with an anti-stiction functionalized oxoacid, in accordance with various examples.

### DETAILED DESCRIPTION

As described above, microelectromechanical systems (MEMS) devices integrate mechanical and electrical components on a single chip. The mechanical components, which may number in the dozens, hundreds, or thousands, are configured to engage in small movements that enable the function of the MEMS device. For example, one type of MEMS device, known as a digital micromirror device (DMD), may include an array of micron-scale mirrors that tilt in different directions to control the propagation of light. MEMS components, such as these small mirrors, can be susceptible to stiction, which is the adhesion or sticking of moving parts within a MEMS device, typically due to surface forces such as van der Waals or electrostatic forces. For example, in DMDs, stiction can cause the mirrors to become stuck in one position. Similar problems with stiction may be encountered in other types of MEMS devices that contain mirrors, such as certain types of optical coherence tomography (OCT) scanners, MEMS-based laser beam steering systems, and grating light valve arrays. Similarly, in MEMS accelerometers, a movable proof mass moves with reference to a fixed electrode, with the movement indicating the degree of acceleration. The proof mass may experience stiction vis-à-vis the fixed electrode, especially at lower spring constants that result in greater accelerometer sensitivity. This stiction can significantly impact the accuracy of acceleration measurements. Likewise, in microcantilevered atomic force microscopes (AFMs), the microcantilevers, which are useful for high-resolution surface imaging, experience stiction due to van der Waals forces or capillary forces, especially in humid environments. This stiction can significantly impact AFM device accuracy. In addition, in microvalves of MEMS fluidic devices, which are useful to control fluid flow in MEMS-based fluidic systems (e.g., lab-on-a-chip devices), stiction can occur due to surface tension of the liquid, electrostatic forces, or contamination. This stiction can prevent the valve from opening and closing properly, leading to malfunction of the system.

Stiction can cause impaired MEMS device functionality, mechanical wear and tear, deformation of moving parts, and irreversible adhesion between surfaces. In some applications, such as optical devices (e.g., projectors), stiction can result in diminished or unacceptable image quality. In applications such as automobiles, aerospace, and medical devices, where reliability and precision are particularly important, stiction-induced failures can have serious consequences, up to and including the loss of human life.

This disclosure describes various examples of MEMS devices coated with films including functionalized oxoacids. Lubricants including functionalized oxoacids function to mitigate stiction among moving components in the MEMS device, thereby reducing the likelihood that the MEMS device will experience the structural and functional degradation described above. In addition to mitigating stiction, the lubricants including functionalized oxoacids may shield the MEMS devices from water, reduce corrosion, and reduce residue and residue buildup. In some examples, a MEMS device includes a moveable element configured to contact a portion of a surface and a lubricant including a functionalized oxoacid on a portion of the surface. Various chemical compositions of the functionalized oxoacids are now described with reference to the drawings.

Herein a functionalized oxoacid for use in the lubricant includes a head portion and a tail portion. In one or more examples, the head portion includes an oxoacid moiety and the tail portion includes a hydrophobic moiety.

In one or more examples, the head portion of the functionalized oxoacid includes an oxoacid moiety. An oxoacid moiety refers to a derivative of a compound that contains hydrogen, oxygen, and at least one other element, with at least one hydrogen atom bonded to oxygen (hydroxyl group) that can dissociate to produce the H⁺ cation and the anion of the acid. The general formula of the oxoacid moiety is AO(OH)ₙ. In one or more examples, an oxoacid moiety that is a component of the functionalized oxoacid includes at least two hydroxyl groups (i.e., n≥2).

In one or more examples, the oxoacid moiety comprises phosphorous. In such examples, the oxoacid moiety may comprise a moiety derived from orthophosphoric acid PO(OH)₂, pyrophosphoric acid [P(OH)₂]O, pyrophosphorus acid [(HO)₂P(O)]₂O, or combinations thereof. When describing a group as being “derived by,” “derived from,” “formed by,” or “formed from,” such terms are used in a formal sense and are not intended to reflect any specific synthetic methods or procedure, unless specified otherwise or the context requires otherwise. For example, the oxoacid moiety is similar to the indicated acid structures having a hydrogen atom removed to allow for a bonding vacancy.

In one or more examples, the functionalized oxoacid includes a tail including a hydrophobic moiety. The hydrophobic moiety may be characterized by an A value of greater than or equal to about 3 kilocalories per mole (kcal/mole), alternatively from about 2 kcal/mole to about 5 kcal/mole, or alternatively from about 3 kcal/mole to about 4 kcal/mole. The A value is a measure of steric strain of a chemical group (the higher the A value, the more severe the steric strain), which in turn is roughly a measure of the size or bulk of the group (the more severe the steric strain, the bulkier the chemical group). High strain (A value greater than or equal to 3 kcal/mole) tail moieties are advantageous due to their increased mechanical rigidity, making it difficult for two contacting surfaces terminated in high strain tail moieties to favorably interact. These high strain terminated surfaces require more energy to flex to accommodate the displacement required to entwine with the other tail moieties on the contacting surface. Higher strains may provide increased benefit. However, some mechanical advantage may still be present in tail moieties with A values between 3-4 kcal/mole, which is comparable to the A values of a CH₃—CH₃ chain (2.6 kcal/mole) or a CH₃—CH₂—CH₂—CH₃ chain (4.5 kcal/mole). Strains below 2 kcal/mole, comparable to a C—H bond in CH₃—CH₃ (1.4 kcal/mole) may not provide significant benefit.

In one or more examples, the hydrophobic moiety includes an aryl group. The aryl group may be substituted or unsubstituted. An “aryl group” is a group derived from the formal removal of a hydrogen atom from an aromatic ring carbon of an arene. An arene refers to aromatic hydrocarbon, with or without side chains (e.g., benzene, toluene, or xylene, among others). The arene can contain a single aromatic hydrocarbon ring (e.g., benzene or toluene), contain fused aromatic rings (e.g., naphthalene or anthracene), or include one or more isolated aromatic rings covalently linked via a bond (e.g., biphenyl) or non-aromatic hydrocarbon group(s) (e.g., diphenylmethane).

An “arene group” refers to a generalized group formed by removing one or more hydrogen atoms from an arene. Similarly, an “arylene group” refers to a group formed by removing two hydrogen atoms (at least one of which is from an aromatic ring carbon) from an arene. A phenyl group (or phenylene group) and/or a naphthyl group (or naphthylene group) refer to the specific unsubstituted arene groups (including no hydrocarbyl group located on an aromatic hydrocarbon ring or ring system carbon atom). Consequently, a substituted phenyl group or substituted naphthyl group refers to the respective arene group having one or more substituent groups (e.g., halogens, hydrocarbyl groups, or hydrocarboxy groups, among others) located on an aromatic hydrocarbon ring or ring system carbon atom.

In one or more examples, the hydrophobic moiety includes a heterocyclic compound. As used herein, a “heterocyclic compound” is a cyclic compound having at least two different elements as ring member atoms. For example, heterocyclic compounds may comprise rings containing carbon and nitrogen (for example, tetrahydropyr-role), carbon and oxygen (for example, tetrahydrofuran), or carbon and sulfur (for example, tetrahydrothiophene), among others. Heterocyclic compounds and heterocyclic groups may be either aliphatic or aromatic.

In one or more aspects, the hydrophobic moiety comprises an unsubstituted aromatic group, a substituted aromatic group, a substituted phenyl group, an unsubstituted phenyl group, a substituted pyridinyl group, an unsubstituted pyridinyl group, a substituted furyl group, an unsubstituted furyl group, a substituted thienyl group, an unsubstituted thienyl group, a substituted cycloalkyl group, an unsubstituted cycloalkyl group, a substituted heterocyclic group, an unsubstituted heterocyclic group, a substituted cycloheteryl group, an unsubstituted cycloheteryl group, a substituted aryl group, an unsubstituted aryl group, a substituted aralkyl group, an unsubstituted aralkyl group, a substituted heteroaryl group, an unsubstituted heteroaryl group, a substituted arylheteryl group, an unsubstituted arylheteryl group, an acene, a carbazole, a fluorene, a diaryl ether, a diarylethylamine, a haloarene, an anthracene, an indene, a napthalene, a phenolate, a pyrene, a phenanthrene, a derivative thereof, or combinations thereof. These and similar groups provide advantage through their steric hindrance as a result of their bulky shapes. This steric hindrance prevents very close contact between two contacting surfaces, minimizing the interaction and stiction between the two surfaces.

In one or more examples, the lubricant may consist essentially of a functionalized oxoacid of the type disclosed herein in the absence of any other additives (e.g., surfactants, emulsifiers, solvents). In an example, the lubricant includes a functionalized oxoacid mixed with a base fluid that facilitates one or more user and/or process goals. For example, the base fluid may be chosen to provide features such as a desired rheology or to adjust concentration. In one or more examples, the base fluid includes hydrocarbons, hydrocarbon oils, or combinations thereof including, but not limited to, n-decane, n-hexadecane, and polyalphaolefin oils.

In one or more examples, the lubricant including a functionalized oxoacid is prepared to provide a final amount of functionalized oxoacids on the surface to which it is applied from about 1×10⁻² mg/cm² to about 1×10⁻¹ mg/cm², alternatively from about 2.5×10⁻² mg/cm² to about 1×10⁻¹ mg/cm² or, alternatively, from about 5×10⁻² mg/cm² to about 1×10⁻¹ mg/cm² based on the total area of the surface.

In one or more examples, a movable component of a MEMS device is in contact with one or more surfaces. The movable component may be in contact with the one or more surfaces continuously. In other examples, the movable component is in contact with the one or more surfaces intermittently.

In an example, the lubricant including a functionalized oxoacid is in contact with at least a portion of the one or more surfaces. Any suitable technique may be useful to contact the one or more surfaces with the lubricant including a functionalized oxoacid. As described below, non-limiting examples of methods for contacting the one or more surfaces with the lubricant including a functionalized oxoacid include deposition, chemical vapor deposition, dip coating, aerosol coating, spray coating, or a combination thereof.

Contacting of the lubricant including a functionalized oxoacid with at least a portion of the one or more surfaces is performed under conditions suitable for the formation of at least one layer (film) of the lubricant including a functionalized oxoacid on the one or more surfaces. In some examples, the lubricant including a functionalized oxoacid self-assembles to form a film. As used herein, self-assembly refers to the process by which a disordered system of pre-existing components forms an organized structure or pattern as a consequence of specific, local interactions among the components themselves, without external direction. Self-assembly occurs when molecules interact with one another through a balance of attractive and repulsive interactions. These interactions are generally weak (that is, comparable to thermal energies) and noncovalent (e.g., van der Waals and Coulomb interactions, hydrophobic interactions, and hydrogen bonds) but relatively weak covalent bonds (e.g., coordination bonds) are recognized increasingly as appropriate for self-assembly, Complementarity in shapes among the self-assembling components is also a factor.

In an example, the surface includes one or more metals, one or more metal oxides or combinations thereof. For example, the surface includes one or more of aluminum, aluminum oxides, aluminum hydroxide, aluminum alloys, titanium, copper, steel, silicon or combinations thereof. In one or more examples, a surface for use in the present disclosure is characterized by the presence of reactive hydroxy groups (—OH) able to associate with one or more atoms in the oxoacid moiety of the functionalized oxoacids. In one or more aspects, at least a portion of one or more surfaces of a device (e.g., DMD) includes hydroxyl groups or hydroxyl precursor groups. In an example, the oxoacid moiety comprises a phosphorous atom which forms a bond with an oxygen-containing group (e.g., —OH group) associated with the one or more surfaces.

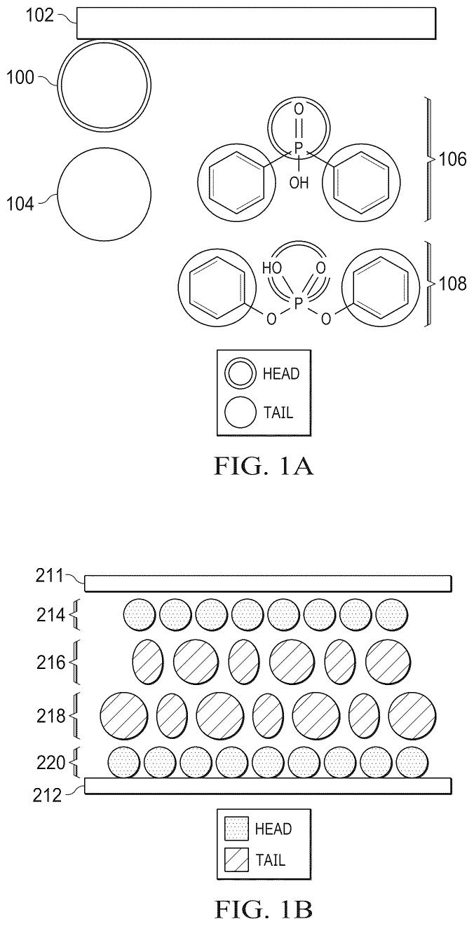

FIG. 1A is a schematic depiction of functionalized oxoacids exemplified by structure 106 and structure 108 adsorbing onto a surface 102 (e.g., a metal surface) and the subsequent ordering of the functionalized oxoacids. Specifically, the functionalized oxoacids 106, 108, once applied to the surface 102 of the MEMS device based on charge and chemical interactions, will orient the head group 100 of the functionalized oxoacid toward the surface. The hydrophobic tail of the functionalized oxoacid 104 will project away from the surface 102. FIG. 1B depicts head groups oriented toward respective surfaces 211, 212. Specifically, head groups 214 are oriented toward surface 211 and head groups 220 are oriented toward surface 212. The tail groups 216 and 218 project away from their associated surfaces 211 and 212, respectively. The functionalized oxoacids will interact through pi bonding and form stacked structures. These stacked structures reduce direct contact between moving parts and reduce surface energy, resulting in a reduction in friction and wear, particularly in the boundary lubrication wear regime.

In one or more examples, the films formed by association of the functionalized oxoacids with the one or more surfaces covers at least 50% of the exposed area of the one or more surfaces, alternatively from about 50% to about 90% or, alternatively, from about 75% to about 95%. Increased coverage of exposed areas may yield more benefit. A 75% to 95% coverage may impart the greatest benefit. A 50% to 90% coverage may provide enough benefit to yield an operable unit, although inferior to the 75% to 95% range. In one or more examples, the film is a monolayer, sub-monolayer, or multilayer having a thickness from about 1 nm to about 50 nm, alternatively from about 1 nm to about 40 nm or, alternatively, from about 1 nm to about 25 nm. The upper bound of film thickness will depend on the size of the chosen molecule to comprise the layer, the bond length of the molecule to the surface, and the ability for the molecule to stack and form multiple layers.

In other examples, the functionalized oxoacid is in contact with the one or more surfaces a plurality of times under conditions suitable for the formation of a multilayer film. In such examples, the multilayer film may have from 2 to 5 layers with each layer having a thickness ranging from about 1 nm to about 50 nm. In such examples, the first film layer, designated Fₘ, may be in contact with the one or more surfaces while additional film layers (Fₘ₊₁, Fₘ₊₂, etc.) may be disposed on the previous film layer. This film, designated FO-FILM, may reduce both direct contact between the moving parts of the MEMS device and the surface energy of the MEMS device. Additionally, the FO-FILM consisting of oxoacid moieties as heads tethered to the metal surface and tails including hydrophobic moieties may display a more rigid structure due to stacking of the non-polar (hydrophobic) portions of the molecules resulting in increased structural integrity that promotes the film having sufficient rigidity to allow it to remain in a position to provide lubrication of the one or more surfaces.

In an example, the FO-FILM is characterized by a contact angle of greater than about 80°, from about 80° to about 150°, or from about 80° to about 120°, where the contact angle is determined in accordance with ASTM (formerly known as American Society for Testing and Materials) D5946. The contact angle, θ (theta), is a quantitative measure of wetting of a solid by a liquid. The contact angle is geometrically defined as the angle formed by a liquid at the three-phase boundary where a liquid, gas, and solid intersect. Larger contact angles indicate higher levels of hydrophobicity, resistance to corrosion, and better lubrication.

In an example, the FO-FILM is characterized by a coefficient of friction of less than about 0.1 to about 0.099, from about 0.05 to about 0.095, or from about 0.025 to about 0.090. The coefficient of friction (COF) is a unitless number that represents the resistance to sliding of two surfaces in contact with each other. A lower COF indicates lower friction force and better lubrication.

In an example, an FO-FILM having a plurality of layers is characterized by an ability to self-heal when the structural integrity of the FO-FILM is compromised. For example, a multilayer FO-FILM having a first layer Fₘ₁ in contact with the one or more surfaces may experience some loss of structural integrity. The loss of structural integrity may be due to, for example, removal of some portion of the film over time. Advantageously, areas having some portion of the first layer Fₘ₁ structurally compromised may have lubrication provided by the presence of adjacent film layers Fₘ₂, Fₘ₃, etc.

In one or more examples, the FO-FILM disclosed herein mitigates the challenges resulting from stiction. For example, FO-FILMs of the present disclosure may display a resistance to the temperatures associated with the processes used for formation of the MEMS device. For example, FO-FILMs may maintain their functional integrity at temperatures ranging from about 25° C. to about 300° C., from about 25° C. to about 250° C., or from about 25° C. to about 200° C. Films that can survive higher temperatures can survive a larger number of processes, allowing for the film to be applied earlier on in the manufacturing flow. As used herein, “maintain functional integrity” refers to the ability of the FO-FILM to continue to provide lubrication after exposure to these temperatures as evidenced by a COF value within the ranges disclosed herein. In alternative examples, the MEMS device may be resistant to corrosion as determined by maintaining the non-wettability and contact angle within the ranges disclosed herein.

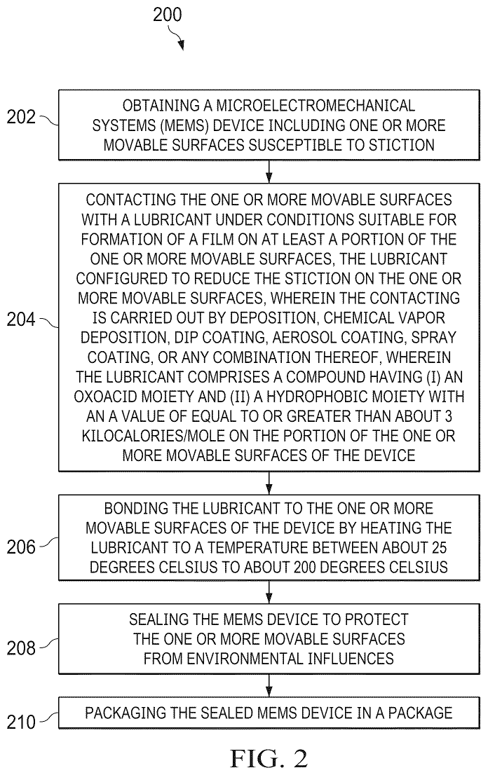

FIG. 2 is a flow diagram of a method 200 for manufacturing a MEMS device lubricated with anti-stiction functionalized oxoacid, in accordance with various examples. The method 200 may include obtaining a MEMS device including one or more movable surfaces susceptible to stiction (202). The MEMS device may include any suitable type of device, such as a DMD, accelerometer, gyroscope, pressure sensor, microphone, printhead, microvalve, optical switch, thermal actuator, micropump, magnetometer, etc. Obtaining a MEMS device may include manufacturing the MEMS device, purchasing the MEMS device, or any other acquisition of the MEMS device. In each MEMS device, different types of components may be susceptible to stiction. For example, in a DMD, mirrors and mirror-supporting structures may be susceptible to stiction, while in a gyroscope, a resonating element may be susceptible to stiction.

The method 200 may include contacting the one or more movable surfaces of the MEMS device with a lubricant (e.g., any of the chemical compounds described herein) under conditions suitable for formation of a film on at least a portion of the one or more movable surfaces of the device (204). The lubricant is configured to reduce the stiction on the one or more movable surfaces (204). The lubricant includes a compound having (i) an oxoacid moiety and (ii) a hydrophobic moiety with an A value of equal to or greater than about 3 kilocalories/mole on the portion of the one or more movable surfaces of the device. The contacting may be performed by deposition, chemical vapor deposition, dip coating, aerosol coating, spray coating, or any combination thereof (204). (The MEMS device provided in step 202 is configured such that the one or more surfaces on which the lubricant is to be applied is accessible to the equipment that will subsequently be used in step 204 to apply the lubricant. Thus, for example, in the context of a DMD, the micromirror array of the DMD may not have been sealed prior to step 204.) In step 204, the lubricant may be applied at least to the one or more surfaces that are susceptible to stiction, and, depending on the application technique, to additional surface(s) of the MEMS device as well. In some examples, the lubricant may be applied indiscriminately to the MEMS device, including to the one or more surfaces susceptible to stiction.

The method 200 may include bonding the lubricant to the one or more movable surfaces of the device by heating the lubricant to a temperature between about 25° C. to about 200° C. (206). Any suitable heating element or device may be used to heat the lubricant once applied to the surface. For example, heating may be carried out in an oven, contacting with a laser device, torch or combinations thereof. Activating the lubricant by heating may result in the formation of a uniform reaction layer (film) between the functionalized oxoacid and the metal surface that increases the lubricating properties of the film. Heating of the lubricant after application of the functionalized oxoacid to the metal surface may result in an increased oxidation of metals near the surface. Conversion of the elemental metals at or near the surface to their cationic counterpart allows for an increased number of charged interactions between the metal surface and the functionalized oxoacid where such interactions include chemisorption and/or physisorption.

The method 200 may include sealing the MEMS device to protect the one or more movable surfaces from environmental influences (208). For example, a seal, for example a hermetic seal, may be formed to protect components of the MEMS device from environmental contaminants and moisture (e.g., in a DMD, the hermetic seal may protect the DMD micromirror array from moisture and contamination). This seal may be formed by bonding a cover glass or lid over the micromirror array using a hermetic sealing technique, such as glass frit sealing or metal sealing. The material used to seal (e.g., solder) forms a strong, impermeable seal when heated or cured. This hermetic seal may prevent moisture, dust, and other environmental contaminants from entering the device.

The method 200 may include packaging the sealed MEMS device in a package (210). For example, a DMD device may be coupled to metal contacts (e.g., bond pads) in a ceramic substrate package, such as by wire bonding or bumping. Other types of MEMS devices, such as gyroscopes or accelerometers, may be included in ceramic packages, mold compound packages, or other suitable types of packages.

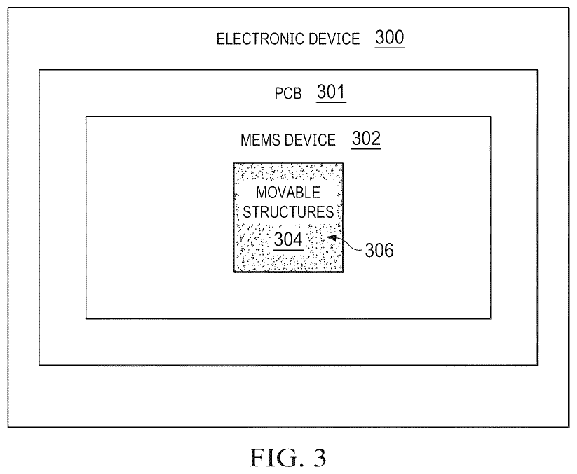

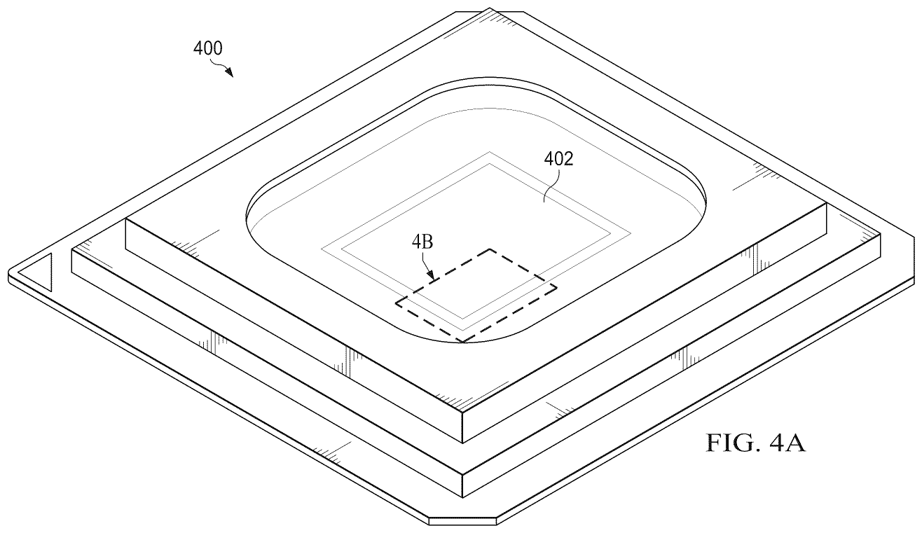

FIG. 3 is a block diagram of a MEMS device lubricated with an anti-stiction functionalized oxoacid, in accordance with various examples. Specifically, FIG. 3 depicts an electronic device 300 including a printed circuit board (PCB) 301 coupled to a MEMS device 302, which, in turn, includes one or more movable structures 304 on which the anti-stiction lubricant 306 (e.g., functionalized oxoacid) is disposed. The PCB 301 is optional. The electronic device 300 may be, for example, an automobile, an aircraft, a watercraft, a spacecraft, a video game console, a smartphone, an entertainment device, an appliance, a laptop computer, a desktop computer, a tablet, a notebook, a projector, or any other suitable type of device or system. The MEMS device 302 may be manufactured according to the method 200, described above. Examples of the MEMS device 302 include DMDs, accelerometers, gyroscopes, pressure sensors, microphones, printheads, microvalves, optical switches, thermal actuators, micropumps, magnetometers, etc. The lubricant 306 (e.g., any of the chemical compounds described herein) may cover one or more areas of the MEMS device 302, including one or more movable structures 304 susceptible to stiction. The lubricant 306 mitigates stiction on surfaces to which it is applied.

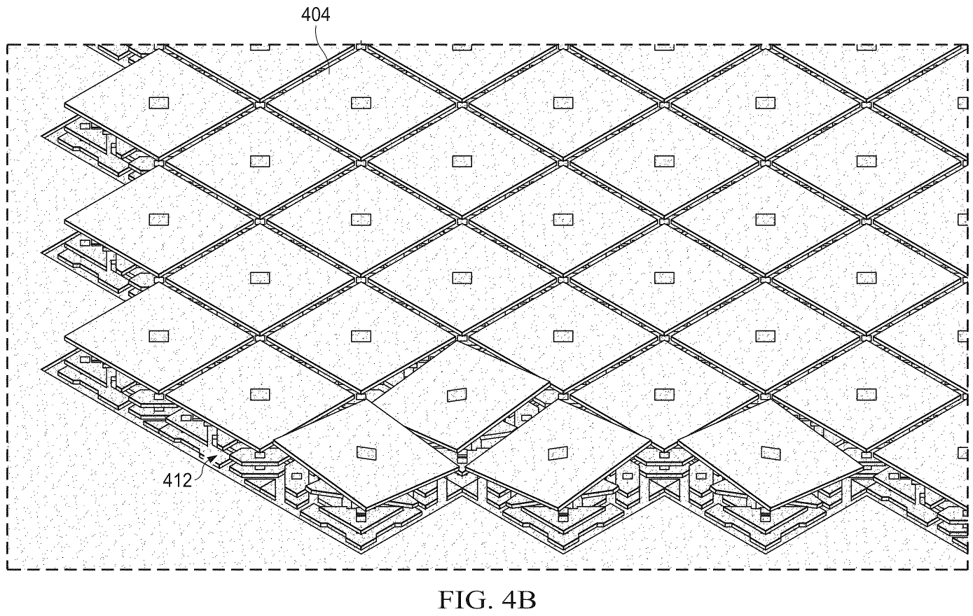

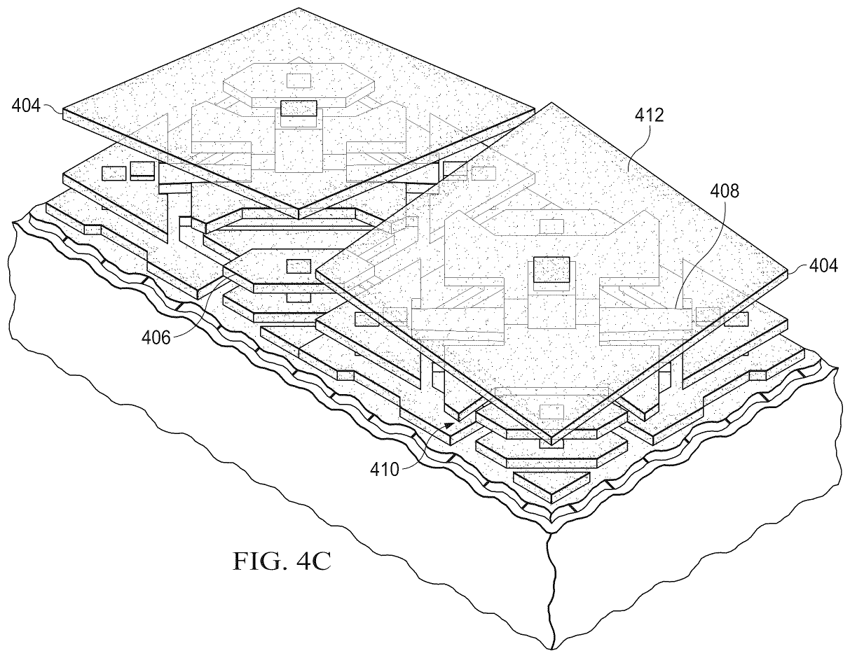

FIGS. 4A-4C are schematic diagrams of a digital micromirror device (DMD) lubricated with an anti-stiction functionalized oxoacid, in accordance with various examples. More specifically, FIG. 4A depicts an example DMD device 400 including a micromirror array 402. The inset in FIG. 4B shows a close-up view of a portion of the micromirror array 402, which includes multiple mirrors 404. The mirrors 404 are configured to tilt in various directions, depending on the direction in which light is to be reflected, as shown in FIG. 4C. The micromirror array 402 may include various components under the mirrors 404 that facilitate movement of the mirrors 404 in response to specific electrical signals. For instance, such components may include electrodes 406, torsion hinges 408, and spring tips 410. The electrodes 406 generate electrostatic fields that cause the respective mirror 404 to tilt in one direction or another; the torsion hinges 408 provide mechanical support and help restore the respective mirror 404 to a neutral, non-tilted state after the electrostatic fields cease; and the spring tips 410 prevent contact between the respective mirror 404 and a respective electrode 406. At least some of the components depicted in FIG. 4C may be susceptible to stiction, and thus a lubricant 412 (e.g., any of the chemical compounds described herein) is applied during manufacture of the DMD device 400 to mitigate stiction and its deleterious effects. The lubricant 412 mitigates stiction on surfaces to which it is applied.

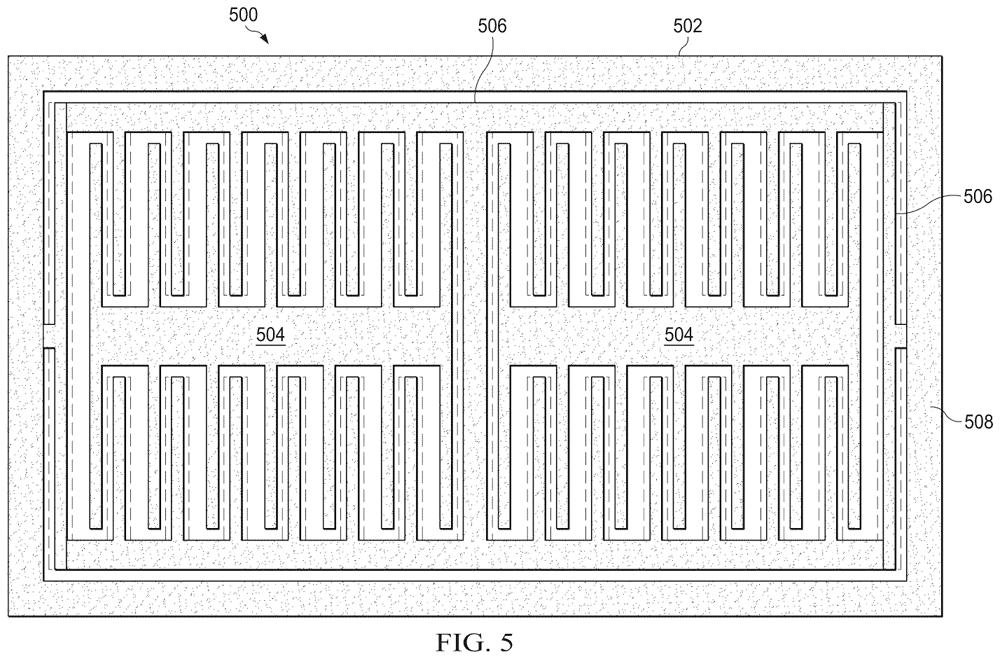

FIG. 5 is a schematic diagram of an accelerometer lubricated with an anti-stiction lubricant (e.g., functionalized oxoacid), in accordance with various examples. Specifically, FIG. 5 depicts moving components of an example MEMS accelerometer 500. The accelerometer 500 includes a support frame 502, fixed electrodes 504, and a movable proof mass 506. Movement of the proof mass 506 relative to the fixed electrodes 504 responsive to acceleration causes capacitive changes that may be sensed by the fixed electrodes 504. As a movable component, the proof mass 506 is susceptible to stiction, particularly as the spring constant is decreased to achieve higher accelerometer sensitivity. A lubricant 508 (e.g., any of the chemical compounds described herein) covers various surfaces, including the movable proof mass 506, and mitigates stiction and the undesirable consequences resulting from stiction. The lubricant 508 mitigates stiction on surfaces to which it is applied.

The MEMS devices shown in FIGS. 4A-4C and 5 are merely illustrative. Any of the chemical compounds described herein may be useful to lubricate any type of MEMS device to mitigate stiction. Further, the scope of application for the chemical compounds described herein is not limited to MEMS devices. Rather, the chemical compounds described herein may be useful to lubricate any type of device with one or more moving components susceptible to stiction.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A. A device that is “configured to” perform a task or function may be configured at a time of manufacturing by a manufacturer to perform the function and/or may be configurable (or reconfigurable) by a user after manufacturing to perform the function and/or other additional or alternative functions. The configuring may be through a construction and/or physical arrangement of hardware components and interconnections of the device, for example.

In this description, unless otherwise stated, “about,” “approximately” or “substantially” preceding a parameter means being within +/−10 percent of that parameter. Modifications are possible in the described examples, and other examples are possible within the scope of the claims.

Unit abbreviations include C for Celsius, cm for centimeters, mg for milligrams, and nm for nanometers.

What is claimed is:

1. A microelectromechanical systems (MEMS) device comprising:
a moveable element configured to contact a portion of a surface; and
a film formed of a self-assembled lubricant, the lubricant comprising a compound having (i) an oxoacid moiety and (ii) a hydrophobic moiety with an A value of equal to or greater than about 3 kilocalories/mole on the portion of the surface.

2. The device of claim 1, wherein the oxoacid moiety comprises at least two hydroxyl groups.

3. The device of claim 1, wherein the oxoacid moiety comprises phosphorus.

4. The device of claim 3, wherein the oxoacid moiety is derived from orthophosphoric acid, pyrophosphoric acid, pyrophosphorus acid, or a combination thereof.

5. The device of claim 1, wherein the hydrophobic moiety with an A value of equal to or greater than about 3 kilocalories/mole comprises at least one unsubstituted aromatic group, at least one substituted aromatic group, or a combination thereof.

6. The device of claim 1, wherein the hydrophobic moiety with an A value of equal to or greater than about 3 kilocalories/mole comprises a substituted phenyl group, an unsubstituted phenyl group, a substituted pyridinyl group, an unsubstituted pyridinyl group, a substituted furyl group, an unsubstituted furyl group, a substituted thienyl group, an unsubstituted thienyl group, a substituted cycloalkyl group, an unsubstituted cycloalkyl group, a substituted heterocyclic group, an unsubstituted heterocyclic group, a substituted cycloheteryl group, an unsubstituted cycloheteryl group, a substituted aryl group, an unsubstituted aryl group, a substituted aralkyl group, an unsubstituted aralkyl group, a substituted heteroaryl group, an unsubstituted heteroaryl group, a substituted arylheteryl group, an unsubstituted arylheteryl group, an acene, a carbazole, a fluorene, a diaryl ether, a diarylethylamine, a haloarene, an anthracene, an indene, a napthalene, a phenolate, a pyrene, a phenanthrene, a derivative thereof, or combinations thereof.

7. The device of claim 1, wherein the film comprises a plurality of layers designated n, and wherein n ranges from 2 to 5.

8. The device of claim 7, wherein each layer in the plurality of layers has a thickness of from about 1 nm to less than about 50 nm.

9. The device of claim 7, wherein the film exhibits a contact angle of equal to or greater than 80 degrees as determined in accordance with ASTM D5946.

10. The device of claim 1, wherein the surface comprises one or more metals, one or more metal oxides, or a combination thereof.

11. The device of claim 1, wherein the surface comprises aluminum, aluminum oxide, or a combination thereof.

12. A method, comprising:
obtaining a microelectromechanical systems (MEMS) device;
contacting one or more surfaces of the MEMS device with a lubricant under conditions suitable for formation of a film on at least a portion of the one or more surfaces of the device, wherein contacting is carried out by deposition, chemical vapor deposition, dip coating, aerosol coating, spray coating, or any combination thereof,
wherein the lubricant comprises a compound having (i) an oxoacid moiety and (ii) a hydrophobic moiety with an A value of equal to or greater than about 3 kilocalories/mole on the portion of the one or more surfaces of the device; and
bonding the lubricant to the one or more surfaces of the device by heating the lubricant to a temperature of from about 25° C. to about 200° C.

13. The method of claim 12, further comprising the lubricant self-assembling to form a film.

14. The method of claim 12, wherein the film comprises a plurality of layers designated n, wherein n ranges from 2 to 5, and wherein each layer has a thickness of from about 1 nm to less than about 50 nm.

15. The method of claim 12, wherein the film is a monolayer having a thickness of from about 1 nm to less than about 50 nm.

16. The method of claim 12, wherein the film exhibits a contact angle of equal to or greater than 80 degrees as determined in accordance with ASTM D5946.

17. The method of claim 12, wherein the oxoacid moiety comprises phosphorus, and wherein the hydrophobic moiety with an A value of equal to or greater than about 3 kilocalories/mole comprises at least one unsubstituted aromatic group, at least one substituted aromatic group, or a combination thereof.

18. A microelectromechanical systems (MEMS) device comprising:
a moveable element configured to contact a portion of a surface; and
a film formed of a self-assembled lubricant on the portion of the surface, wherein the lubricant comprises a compound having (i) an oxoacid moiety comprising phosphorus and (ii) a hydrophobic moiety with an A value of equal to or greater than about 3 kilocalories/mole.

19. The device of claim 18, wherein the oxoacid moiety is derived from orthophosphoric acid, pyrophosphoric acid, pyrophosphorus acid, or a combination thereof.

20. The device of claim 18, wherein the hydrophobic moiety with an A value of equal to or greater than about 3 kilocalories/mole comprises a substituted phenyl group, an unsubstituted phenyl group, a substituted pyridinyl group, an unsubstituted pyridinyl group, a substituted furyl group, an unsubstituted furyl group, a substituted thienyl group, an unsubstituted thienyl group, a substituted cycloalkyl group, an unsubstituted cycloalkyl group, a substituted heterocyclic group, an unsubstituted heterocyclic group, a substituted cycloheteryl group, an unsubstituted cycloheteryl group, a substituted aryl group, an unsubstituted aryl group, a substituted aralkyl group, an unsubstituted aralkyl group, a substituted heteroaryl group, an unsubstituted heteroaryl group, a substituted arylheteryl group, an unsubstituted arylheteryl group, an acene, a carbazole, a fluorene, a diaryl ether, a diarylethylamine, a haloarene, an anthracene, an indene, a napthalene, a phenolate, a pyrene, a phenanthrene, a derivative thereof, or combinations thereof.
